(19) United States
(12) Patent Application Publication
(10) Pub. No.: US 2024/0071920 A1
(43) Pub. Date: Feb. 29, 2024

(54) Barrier-Less Jumper Structure for Line-to-Line Connections

(71) Applicant: International Business Machines Corporation, Armonk, NY (US)

(72) Inventors: Nicholas Anthony Lanzillo, Wynantskill, NY (US); Brent A. Anderson, Essex Junction, VT (US); Albert M. Chu, Nashua, NH (US); Lawrence A. Clevenger, Saratoga Springs, NY (US); Ruilong Xie, Niskayuna, NY (US); Reinaldo Vega, Mahopac, NY (US)

(21) Appl. No.: 17/896,278

(22) Filed: Aug. 26, 2022

(51) Int. Cl. H01L 23/528; H01L 21/768

(52) U.S. Cl. CPC H01L 23/5283; H01L 21/76883; H01L 23/53223

(57) ABSTRACT

A semiconductor apparatus includes a substrate; a first conductive feature disposed on the substrate, the first conductive feature comprising a conductive material; a second conductive feature disposed on the substrate, the second conductive feature comprising the conductive material; a dielectric material at least partially surrounding the first conductive feature and the second conductive feature; and an interconnect between the first conductive feature and the second conductive feature, the interconnect comprising the conductive material integral with the first conductive feature and the second conductive feature and extending through the dielectric material and below the first conductive feature and the second conductive feature.

### BACKGROUND

The exemplary embodiments described herein relate generally to semiconductor devices and methods for the fabrication thereof and, more specifically, to jumpers used for the interconnection of adjacently-positioned lines and vias in integrated circuit devices.

Semiconductor packages generally employ a variety of integrated circuit (IC) devices, typically chips and other circuit elements (such as transistors), mounted on silicon crystal substrates or wafer material. To connect the circuit elements to each other and to impart functionality to the IC devices, interconnection structures are incorporated into the packaging. Such interconnection structures may be wiring lines and/or multi-level or multi-layered interconnection schemes such as vias. The lines and/or multi-level or multi-layer interconnections are generally fabricated on or in the substrates using damascene or dual damascene deposition processes.

In the design and manufacture of the semiconductor packages, and particularly in the layout design phases of the IC devices, same-layer metal interconnecting wires are generally used to avoid the occurrence of line intersection, thus making layout designs complicated due to the large numbers of lines. In order to reduce the complexity of the layout, jumper wires may be used to interconnect adjacent lines.

### BRIEF SUMMARY

In one exemplary aspect, a semiconductor apparatus comprises a substrate; a first conductive feature disposed on the substrate, the first conductive feature comprising a conductive material; a second conductive feature disposed on the substrate, the second conductive feature comprising the conductive material; a dielectric material at least partially surrounding the first conductive feature and the second conductive feature; and an interconnect between the first conductive feature and the second conductive feature, the interconnect comprising the conductive material integral with the first conductive feature and the second conductive feature and extending through the dielectric material and below the first conductive feature and the second conductive feature.

In another exemplary aspect, a semiconductor apparatus comprises a substrate; a first conductive feature disposed on the substrate, the first conductive feature comprising a conductive material; a second conductive feature disposed on the substrate, the second conductive feature comprising the conductive material; a dielectric material at least partially surrounding the first conductive feature and the second conductive feature; and an interconnect between the first conductive feature and the second conductive feature, the interconnect comprising the conductive material integral with the first conductive feature and the second conductive feature and extending above the first conductive feature and the second conductive feature.

In another exemplary aspect, a method comprises depositing a first dielectric material onto a substrate; etching an opening into the first dielectric material; depositing a conductive material into the opening; subtractively etching the deposited conductive material to form a first conductive feature, a second conductive feature, and an interconnect extending below and interconnecting the first conductive feature and the second conductive feature; and depositing a second dielectric material around at least a portion of the first conductive feature, the second conductive feature, and the interconnect.

### BRIEF DESCRIPTION OF THE SEVERAL VIEWS OF THE DRAWINGS

The foregoing and other aspects of exemplary embodiments are made more evident in the following Detailed Description, when read in conjunction with the attached Drawing Figures, wherein:

FIG. 1A is a schematic representation of a top view of metal lines connected using a jumper above the metal lines;

FIG. 1B is a schematic representation of a cross-sectional view of the metal lines and jumper of FIG. 1A;

FIG. 2A is a schematic representation of a top view of metal lines connected using a jumper below the metal lines;

FIG. 2B is a schematic representation of a cross-sectional view of the metal lines and jumper of FIG. 2A;

FIG. 3A is a schematic representation of a top view of metal lines connected using a jumper above the metal lines and without a barrier between the jumper and the metal lines;

FIG. 3B is a schematic representation of a cross-sectional view of the metal lines and jumper of FIG. 3A; and

FIG. 4 is a flow of an example process of forming a barrier-less jumper connection between metal lines.

### DETAILED DESCRIPTION

The word “exemplary” is used herein to mean “serving as an example, instance, or illustration.” Any embodiment described herein as “exemplary” is not necessarily to be construed as preferred or advantageous over other embodiments. All of the embodiments described in this Detailed Description are exemplary embodiments provided to enable persons skilled in the art to make or use the invention and not to limit the scope of the invention which is defined by the claims.

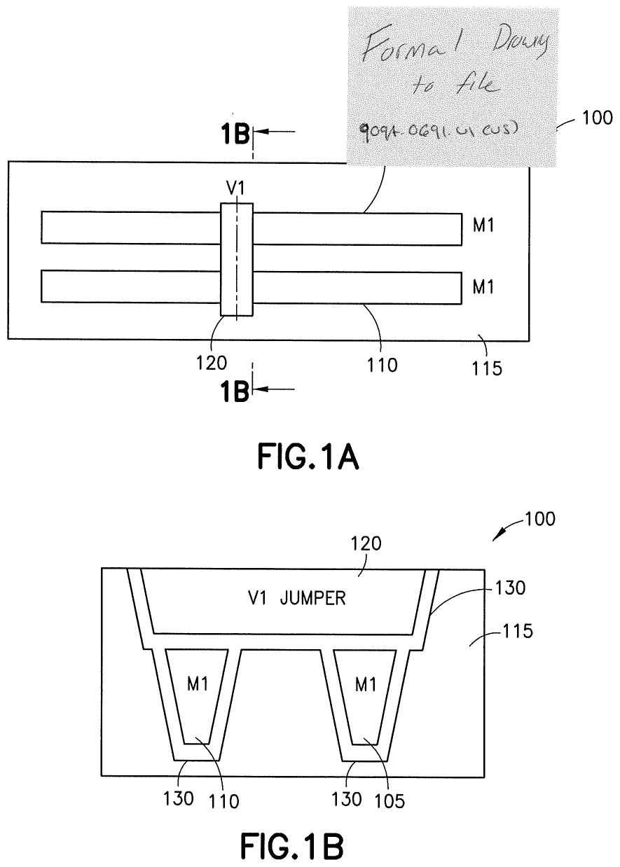

In FIGS. 1A and 1B, an interconnect structure or jumper connection between adjacent conductive structures forming a portion of a semiconductor package is illustrated generally at 100 and is hereinafter referred to as “jumper connection 100.” Although the conductive structures are described as being metal lines, one or more of the conductive structures may be a via. The metal lines and/or vias may be formed by damascene processes.

Jumper connection 100 includes a first metal line 105 positioned adjacent to a second metal line 110 in a dielectric layer 115 and a jumper 120 extending between and in contact with each of the first metal line 105 and the second metal line 110. Although the first metal line 105 and the second metal line 110 are schematically shown as extending parallel to each other in the dielectric layer 115, the first metal line 105 and the second metal line 110 may extend at angles relative to each other.

As shown in FIG. 1B, the jumper 120 extends above the first metal line 105 and the second metal line 110. The jumper 120 includes a conductive material having a barrier 130 as an interface liner positioned between the conductive material of the jumper 120 and each of the respective first metal line 105 and second metal line 110. The barrier 130 also separates the metal lines and the jumper from the material of the dielectric layer 115.

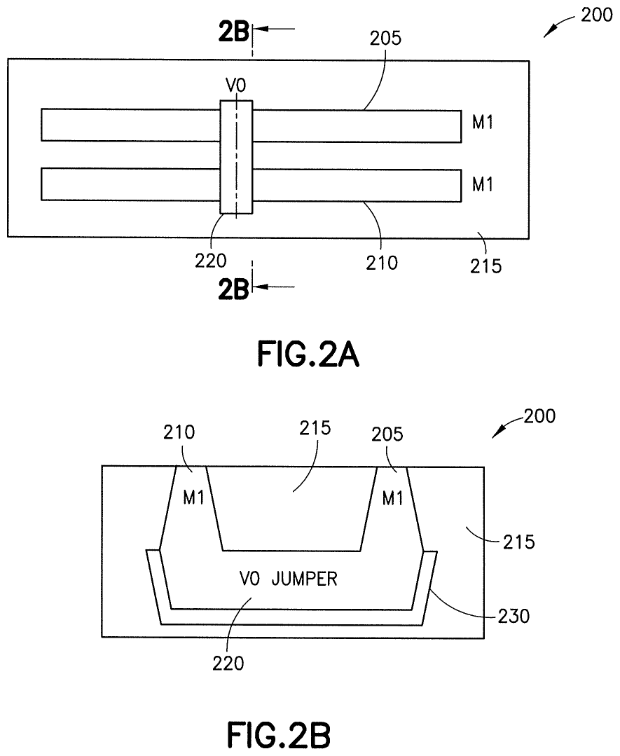

In FIGS. 2A and 2B, one exemplary embodiment of an interconnect structure or jumper connection between adjacent conductive structures forming a portion of a semiconductor package is illustrated generally at 200 and is hereinafter referred to as “jumper connection 200.”

Jumper connection 200 includes a first metal line 205 positioned adjacent to a second metal line 210 in a dielectric layer 215 and a jumper 220 extending between and in contact with each of the first metal line 205 and the second metal line 210. Although the first metal line 205 and the second metal line 210 are schematically shown as extending parallel to each other in the dielectric layer 215, the first metal line 205 and the second metal line 210 may extend at angles relative to each other.

The conductive structures are described as being metal lines, but one or more of the conductive structures may be a via. In example embodiments in which the conductive structures of the jumper structure 200 are metal lines, the metal lines may be formed by subtractive processes. In example embodiments in which the conductive structures of the jumper structure 200 are vias, such vias may be formed by damascene processes or dual-damascene processes. Semi-damascene processes may also be employed in which metal pitches beyond 2 nanometer (nm) are targeted.

As shown in FIG. 2B, the jumper 220 extends below the first metal line 205 and the second metal line 210 and is formed with the first metal line 205 and the second metal line 210 using a subtractive process to form a continuity between the first metal line 205 and the second metal line 210. A barrier 230 as an interface liner may be positioned between each of the respective first metal line 205 and second metal line 210 and the conductive material of the jumper 220.

The material of the dielectric layer 215 may be any suitable dielectric material, for example, silicon dioxide or silicon dioxide doped with carbon. The material of the first metal line 205 and the second metal line 210 may be any suitable conductive material, such as tungsten, aluminum, silver, cobalt, copper, gold, or ruthenium or alloys of any of the foregoing materials. The jumper 220 may be a conductive material that is the same as the material of the first and second metal lines. The material of the barrier 230 or liner interface may be any suitable metal barrier material such as Ta, TaN, or TiN. The barrier 230 provides a separation between the material of the jumper 220 and material of the substrate (not shown) in which the jumper 220 is disposed.

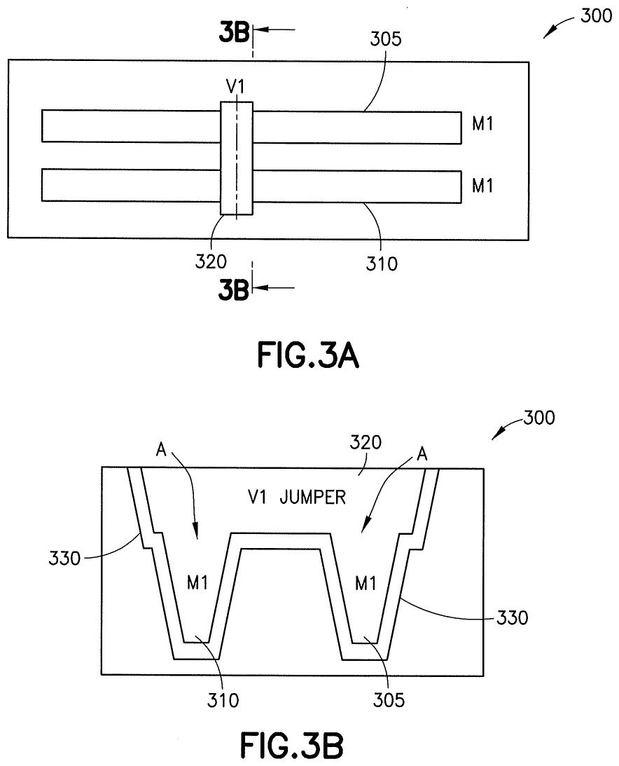

In FIGS. 3A and 3B, another exemplary embodiment of an interconnect or jumper connection between adjacent conductive structures forming a portion of a semiconductor package is illustrated generally at 300 and is hereinafter referred to as “jumper connection 300.” Although the conductive structures are described as being metal lines, one or more of the conductive structures may be a via. In example embodiments of either metal lines or vias, the conductive structures may be formed by damascene processes or dual-damascene processes. Semi-damascene processes may also be used.

As shown in FIG. 3B, a jumper 320 extends above a first metal line 305 and a second metal line 310 and is formed with the first metal line 305 and the second metal line 310 using any suitable type of damascene process to form a continuity between the first metal line 305 and the second metal line 310. A barrier 330 or liner interface is disposed on the jumper 320, the first metal line 305, and the second metal line 310. However, an RSB process may be used to remove portions of the barrier 330 at the interfaces of the jumper 320 and each of the first metal line 305 and the second metal line 310 (shown at A). In embodiments in which the conductive structures are vias (as opposed to the first metal line 305 and the second metal line 310), the via structures include the barrier 330 at the bottom and side portions of the vias without barrier material directly above the vias and between the vias and the jumper 320. As in other example embodiments, the jumper 320 may be a conductive material, and the material of the barrier 330 includes any suitable metal barrier material such as Ta, TaN, or TiN.

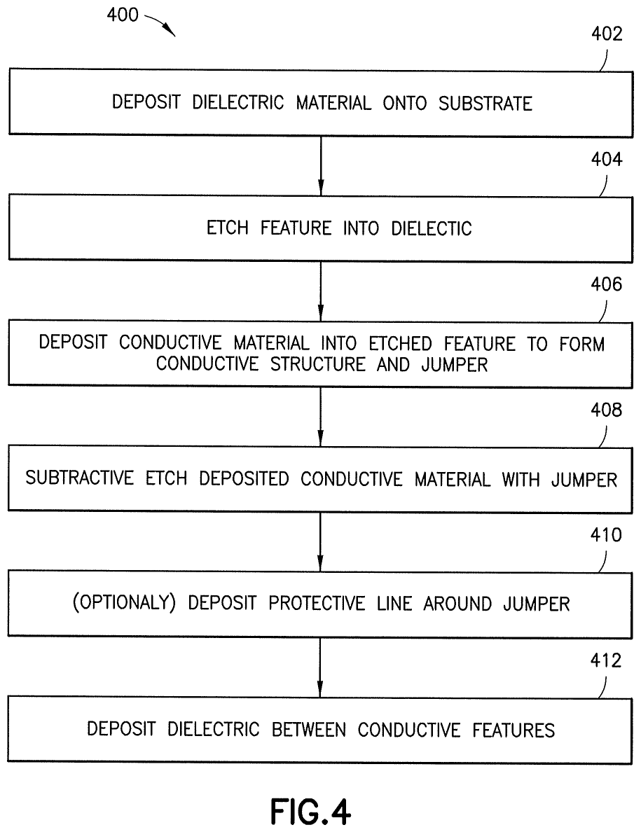

Referring now to FIG. 4, a flowchart illustrating one exemplary embodiment of a method of forming a barrier-less jumper structure is shown generally at 400 and is hereinafter referred to as “method 400.” Method 400 includes, as shown at block 402, depositing a dielectric material onto a substrate. Any suitable deposition technique may be used to deposit the dielectric, including, but not limited to, physical vapor deposition (PVD), chemical vapor deposition (CVD), plasma enhanced chemical vapor deposition (PECVD), atomic layer deposition (ALD), or the like.

Subsequent to the deposition of the dielectric material, one or more openings are etched into the dielectric, as shown at block 404. Etching is also carried out to accommodate a jumper between selected features. Etching may be carried out, for example, by reactive ion etching (RIE) or the like. In the etching step, outer edges of the opening(s) are extended to accommodate the (optional) deposition of the barrier in a later step.

As shown by block 406, a conductive material is deposited into the openings etched into the dielectric, thereby filling the openings to form conductive structures and jumpers between selected conductive structures. Deposition of the conductive material may be by any suitable technique, such as PCD, CVD, PECVD, ALD, or the like.

As shown by block 408, a subtractive etch may be used to define the conductive material deposited into the openings etched into the dielectric. Such a process generally defines the deposited conductive material as conductive structures in the form of lines or vias (or other features). The subtractive etch also defines the jumper between two or more selected conductive structures. In using the subtractive etch in this manner, a gap may be formed between the defined wall of a conductive structure and a wall of the dielectric.

As shown at the optional block 410, a barrier material may be deposited into the gap formed between the conductive structure forming the line or via and the dielectric. If deposited, the barrier material forms a liner interface. Also, if deposited, there is no barrier material forming a liner interface between the conductive structures and the jumper. In other words, continuity of material is maintained between selected conductive structures and the jumper.

As shown at block 412, a second deposition of dielectric material may be deposited around the formed conductive structures. The jumper is buried below the conductive structures.

Method 400 may be modified as needed to produce the jumper 320 extending above conductive structures (first metal line 305 and second metal line 310) as described above with regard to FIGS. 3A and 3B. The method may also be modified or steps may be carried out to result in a configuration without the barrier 330 at the interfaces of the jumper 320 and each of the first metal line 305 and the second metal line 310.

The above-described exemplary embodiments exhibit various high-value attributes. For example, both the jumper structures having the jumper below the lines and above the lines without the barrier at the interfaces of the jumper and each of the lines enables jumpers of low-resistance to be placed between adjacent lines (or other structures). Additionally, barrier removal may result in greater than 50% via resistance reduction. Also, the exemplary embodiments described herein enable design flexibility due to neighboring lines (or other structures) being able to exchange current. Furthermore, the jumper structures as described herein are easily detectable in a semiconductor package.

In one aspect, a semiconductor apparatus comprises a substrate; a first conductive feature disposed on the substrate, the first conductive feature comprising a conductive material; a second conductive feature disposed on the substrate, the second conductive feature comprising the conductive material; a dielectric material at least partially surrounding the first conductive feature and the second conductive feature; and an interconnect between the first conductive feature and the second conductive feature, the interconnect comprising the conductive material integral with the first conductive feature and the second conductive feature and extending through the dielectric material and below the first conductive feature and the second conductive feature.

At least one of the first conductive feature and the second conductive feature may be a subtractive etch feature comprising the conductive material. At least one of the first conductive feature and the second conductive feature may be a damascene feature comprising the conductive material. The first conductive feature may be one of a damascene feature or a subtractive etch feature, and the second conductive feature may be the other of the subtractive etch feature or the damascene feature. The semiconductor apparatus may further comprise a metal barrier between the interconnect and the dielectric material. The metal barrier may comprise Ta, TaN, or TiN. The dielectric material may be silicon dioxide. The conductive material may be selected from the group consisting of tungsten, aluminum, silver, cobalt, copper, gold, ruthenium, and alloys thereof.

In another aspect, a semiconductor apparatus comprises a substrate; a first conductive feature disposed on the substrate, the first conductive feature comprising a conductive material; a second conductive feature disposed on the substrate, the second conductive feature comprising the conductive material; a dielectric material at least partially surrounding the first conductive feature and the second conductive feature; and an interconnect between the first conductive feature and the second conductive feature, the interconnect comprising the conductive material integral with the first conductive feature and the second conductive feature and extending above the first conductive feature and the second conductive feature.

The first conductive feature and the second conductive feature may be damascene features comprising the conductive material. The semiconductor apparatus may further comprise a metal barrier between the interconnect and the dielectric material and between each of the first conductive feature and the second conductive feature and the dielectric material. The metal barrier may comprise Ta, TaN, or TiN. The dielectric material may be silicon dioxide. The conductive material may be selected from the group consisting of tungsten, aluminum, silver, cobalt, copper, gold, ruthenium, and alloys thereof.

In another aspect, a method comprises depositing a first dielectric material onto a substrate; etching an opening into the first dielectric material; depositing a conductive material into the opening; subtractively etching the deposited conductive material to form a first conductive feature, a second conductive feature, and an interconnect extending below and interconnecting the first conductive feature and the second conductive feature; and depositing a second dielectric material around at least a portion of the first conductive feature, the second conductive feature, and the interconnect.

Subtractively etching the deposited conductive material may form a gap around at least one of the first conductive feature, the second conductive feature, or the interconnect. The method may further comprise depositing a protective liner into the gap. Depositing the conductive material may comprise depositing using physical vapor deposition, chemical vapor deposition, plasma-enhanced chemical vapor deposition, or atomic layer deposition. The conductive material may be selected from the group consisting of tungsten, aluminum, silver, cobalt, copper, gold, ruthenium, and alloys thereof.

In the foregoing description, numerous specific details are set forth, such as particular structures, components, materials, dimensions, processing steps, and techniques, in order to provide a thorough understanding of the exemplary embodiments disclosed herein. However, it will be appreciated by one of ordinary skill of the art that the exemplary embodiments disclosed herein may be practiced without these specific details. Additionally, details of well-known structures or processing steps may have been omitted or may have not been described in order to avoid obscuring the presented embodiments. It will be understood that when an element as a layer, region, or substrate is referred to as being “on” or “over” another element, it can be directly on the other element or intervening elements may also be present. In contrast, when an element is referred to as being “directly on” or “directly” over another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The description of the present invention has been presented for purposes of illustration and description, but is not intended to be exhaustive or limiting in the form disclosed. Many modifications and variations will be apparent to those of ordinary skill in the art without departing from the scope of the invention. The embodiments were chosen and described in order to best explain the principles of the invention and the practical applications, and to enable others of ordinary skill in the art to understand the invention for various embodiments with various modifications as are suited to the particular uses contemplated.

What is claimed is:

1. A semiconductor apparatus, comprising:
a substrate;
a first conductive feature disposed on the substrate, the first conductive feature comprising a conductive material;
a second conductive feature disposed on the substrate, the second conductive feature comprising the conductive material;
a dielectric material at least partially surrounding the first conductive feature and the second conductive feature; and
an interconnect between the first conductive feature and the second conductive feature, the interconnect comprising the conductive material integral with the first conductive feature and the second conductive feature and extending through the dielectric material and below the first conductive feature and the second conductive feature.

2. The semiconductor apparatus of claim 1, wherein at least one of the first conductive feature and the second conductive feature is a subtractive etch feature comprising the conductive material.

3. The semiconductor apparatus of claim 1, wherein at least one of the first conductive feature and the second conductive feature is a damascene feature comprising the conductive material.

4. The semiconductor apparatus of claim 1, wherein the first conductive feature is one of a damascene feature or a subtractive etch feature, and wherein the second conductive feature is the other of the subtractive etch feature or the damascene feature.

5. The semiconductor apparatus of claim 1, further comprising a metal barrier between the interconnect and the dielectric material.

6. The semiconductor apparatus of claim 5, wherein the metal barrier comprises Ta, TaN, or TiN.

7. The semiconductor apparatus of claim 1, wherein the dielectric material is silicon dioxide.

8. The semiconductor apparatus of claim 1, wherein the conductive material is selected from the group consisting of tungsten, aluminum, silver, cobalt, copper, gold, ruthenium, and alloys thereof.

9. A semiconductor apparatus, comprising:
a substrate;
a first conductive feature disposed on the substrate, the first conductive feature comprising a conductive material;
a second conductive feature disposed on the substrate, the second conductive feature comprising the conductive material;
a dielectric material at least partially surrounding the first conductive feature and the second conductive feature; and
an interconnect between the first conductive feature and the second conductive feature, the interconnect comprising the conductive material integral with the first conductive feature and the second conductive feature and extending above the first conductive feature and the second conductive feature.

10. The semiconductor apparatus of claim 9, wherein the first conductive feature and the second conductive feature are damascene features comprising the conductive material.

11. The semiconductor apparatus of claim 9, further comprising a metal barrier between the interconnect and the dielectric material and between each of the first conductive feature and the second conductive feature and the dielectric material.

12. The semiconductor apparatus of claim 11, wherein the metal barrier comprises Ta, TaN, or TiN.

13. The semiconductor apparatus of claim 9, wherein the dielectric material is silicon dioxide.

14. The semiconductor apparatus of claim 9, wherein the conductive material is selected from the group consisting of tungsten, aluminum, silver, cobalt, copper, gold, ruthenium, and alloys thereof.

15. A method, comprising:
depositing a first dielectric material onto a substrate;
etching an opening into the first dielectric material;
depositing a conductive material into the opening;
subtractively etching the deposited conductive material to form a first conductive feature, a second conductive feature, and an interconnect extending below and interconnecting the first conductive feature and the second conductive feature; and
depositing a second dielectric material around at least a portion of the first conductive feature, the second conductive feature, and the interconnect.

16. The method of claim 15, wherein subtractively etching the deposited conductive material forms a gap around at least one of the first conductive feature, the second conductive feature, or the interconnect.

17. The method of claim 16, further comprising depositing a protective liner into the gap.

18. The method of claim 15, wherein depositing the conductive material comprises depositing using physical vapor deposition, chemical vapor deposition, plasma-enhanced chemical vapor deposition, or atomic layer deposition.

19. The method of claim 15, wherein the conductive material is selected from the group consisting of tungsten, aluminum, silver, cobalt, copper, gold, ruthenium, and alloys thereof.
